(19) United States
(12) Patent Application Publication
(10) Pub. No.: US 2026/0268992 A1
(43) Pub. Date: Sep. 10, 2026

(54) CONFIGURATION OF MEMORY BASED ON SENSOR DATA

(71) Applicant: Google LLC, Mountain View, CA (US)

(72) Inventors: Subrata Banik, Bangalore (IN); Jayvik Arun Desai, Banglore (IN); Minjia Xu, San Jose, CA (US)

(21) Appl. No.: 19/072,476

(22) Filed: Mar. 6, 2025

(51) Int. Cl. G11C 29/02

(52) U.S. Cl. CPC G11C 29/028; G11C 2207/2254

(57) ABSTRACT

According to at least one implementation, a method includes identifying at least one sensor datum from at least one sensor on a computing device. The method further includes determining that the at least one sensor datum satisfies at least one criterion. In response to the at least one sensor datum satisfying the at least one criterion, the method further includes initiating a calibration of memory on the computing device.

### BACKGROUND

In modern computing devices, memory refers to the hardware components that store data and instructions, either temporarily (volatile memory like random access memory (RAM)) or permanently (non-volatile storage like solid-state drives or hard disk drives), enabling the device to process and retain information. Memory calibration, which can occur during a software update, involves optimizing the memory subsystem to ensure it operates efficiently and reliably, typically by adjusting timing, voltage, or frequency. This process enables a device to operate reliably and efficiently.

### SUMMARY

Systems and operations described herein implement memory calibration on a computing device based on sensor data. In at least one implementation, a computing device can be configured to identify at least one sensor datum from a sensor on the computing device. The sensor can provide temperature, solar radiation, magnetic field, humidity, location, or other data associated with the device. The device can determine whether the at least one datum satisfies at least one criterion. When the at least one datum satisfies the at least one criterion, the device can perform a memory calibration. In some implementations, the device can determine that the criterion is satisfied when the location, temperature, humidity, or other data changes from a first value to a second value by a threshold amount. In some implementations, the device can be configured to apply a model to the at least one datum to generate a value and determine whether the value satisfies criteria to provide a memory calibration.

In some aspects, the techniques described herein relate to a method including: identifying at least one sensor datum from at least one sensor on a computing device; determining that the at least one sensor datum satisfies at least one criterion; and in response to the at least one sensor datum satisfying the at least one criterion, initiating a calibration of memory on the computing device.

In some aspects, the techniques described herein relate to a computer-readable storage medium having program instructions stored thereon that, when executed by at least one processor, direct the at least one processor to perform a method, the method including: identifying at least one sensor datum from at least one sensor on a computing device; determining that the at least one sensor datum satisfies at least one criterion; and in response to the at least one sensor datum satisfying the at least one criterion, initiating a calibration of memory on the computing device.

In some aspects, the techniques described herein relate to a computing apparatus including: computer-readable storage media; at least one processor operatively coupled to the computer-readable storage media; and program instructions stored on the computer-readable storage media that, when executed by the at least one processor, direct the computing apparatus to perform a method, the method including: identifying at least one sensor datum from at least one sensor on a computing device; determining that the at least one sensor datum satisfies at least one criterion; and in response to the at least one sensor datum satisfying the at least one criterion, initiating a calibration of memory on the computing device.

The accompanying drawings and the description below outline the details of one or more implementations. Other features will be apparent from the description, drawings, and claims.

### BRIEF DESCRIPTION OF THE DRAWINGS

FIG. 1 illustrates a computing device that provides memory calibration according to an implementation.

FIG. 2 illustrates a method of operating a computing device to provide memory calibration according to an implementation.

FIG. 3 illustrates an operational scenario of providing memory calibration according to an implementation.

FIG. 4 illustrates an operational scenario of providing memory calibration according to an implementation.

FIG. 5 illustrates an operational scenario of using sensor data to provide memory calibration according to an implementation.

FIG. 6 illustrates an operational scenario of configuring a model to identify memory calibration timing according to an implementation.

FIG. 7 illustrates an operational scenario of using sensor data across multiple devices to configure a model associated with memory calibration timing according to an implementation.

### DETAILED DESCRIPTION

Memory in a computing device refers to the hardware components that store data and instructions for the device to operate. It temporarily or permanently holds information, enabling the processing system (e.g., central processing unit or CPU) to access it for processing tasks. Memory can be categorized into different types, such as volatile memory like RAM (used for temporary data storage during active processes) and non-volatile memory like flash storage or hard drives (used for permanent data storage).

Some computing devices can be configured to perform memory calibration. Memory calibration can include optimizing the performance and reliability of a device’s memory system. It involves adjusting parameters such as voltage, timing, and frequency to ensure that memory modules operate within their specified tolerances and communicate effectively with the processor. This process can be used in modern computing systems to account for variations in memory manufacturing, system design, and environmental factors. Memory calibration provides stability, maximizes data transfer rates, and minimizes errors during operation. However, at least one technical problem exists in determining when to implement memory calibration. Specifically, performing memory calibration so as not to disrupt the user’s workflow and maintain the functionality of the computing device.

In some technical solutions, a computing device can be configured to monitor sensor data from the device and use the sensor data to initiate a memory calibration. Put another way, the computing device can be configured to identify changes in sensor data over time and use the changes to the sensor data to initiate a memory calibration. The sensor data can include Global Positioning System (GPS), temperature, humidity, solar radiation, magnetic field, or other data associated with the device or other sensor data. If the sensor data satisfies at least one criterion, the device can identify that a memory calibration is required. The memory calibration can occur automatically (e.g., during device downtime) or in response to a user’s calibration approval. For example, a phone operating in a first location can travel to a second location with different temperature characteristics. The device can identify that the temperature changes satisfy at least one criterion and initiate an operation to perform the memory calibration on the device. As at least one technical effect, the device can identify sensor data that causes the memory calibration, limiting unnecessary recalibrations or initiating calibrations as required. This limits the downtime associated with unnecessary calibrations and starts calibrations when needed based on the user’s physical environment.

In some implementations, the device can update and use a model to determine when to initiate the memory calibration. Machine learning enables the computing device to learn from data patterns and make predictions or decisions without explicit programming. It allows the device to initiate actions, like memory calibration, based on the patterns and insights derived from past interactions. In at least one example, the computing device can associate the memory status with environmental characteristics (i.e., sensor data) to determine when a memory calibration can occur. In some examples, the device can identify sensor data and determine a memory state (also referred to herein as “memory status information”) associated with or correlating to the sensor data. The memory state can include error information, such as page faults (when a process accesses memory not currently in RAM), out-of-memory errors (when the system runs out of available RAM and swap space), and memory leaks (when applications fail to release unused memory). It can also cover hardware-related errors like Error-Correcting Code (ECC) memory corrections, bad RAM sectors, and segmentation faults caused by invalid memory access. The sensor data can be mapped to and predict potential memory errors, which can be used to cause memory calibration on the device predictively.

Thus, when the sensor data for the device reflects the need for recalibration, the computing device can calibrate the memory on the device. In some examples, the training and updating of the model can use sensor and memory status information from a single device. In other examples, the training and updating of the model can use sensor and memory status information across multiple devices, where the data is compiled into a model that is distributed to individual devices. Advantageously, data points from various devices can contribute to the model that initiates the memory calibration.

In some implementations, the model is configured to associate sensor data or trends in sensor data with potential memory conditions that require calibration. The model can cause the calibration based on the sensor data to implement the memory calibration on the device predictively (i.e., before a potential memory error). In some implementations, the model is applied to the sensor data to generate an output, wherein the output indicates whether a memory calibration is required. In some implementations, the device preprocesses the sensor data through normalization, filtering, or feature extraction. Normalization is scaling sensor data to a standard range (e.g., 0 to 1 or -1 to 1) to ensure that different input values do not disproportionately affect a machine learning model. Filtering involves removing noise or irrelevant variations from sensor input using techniques like moving averages, low-pass filters, or median filters. Feature extraction can transform raw sensor data into meaningful attributes that improve a model’s ability to recognize patterns. This may include computing statistical measures (e.g., mean, variance), identifying frequency components (e.g., via Fourier transform), or detecting key signal patterns relevant to the decision-making process.

The preprocessed data is then fed into the configured model, which has learned patterns from historically labeled examples (i.e., the training provided from associating the sensor data to the memory status information). Using techniques like classification, regression, or anomaly detection, the model evaluates the input against its learned parameters and generates an output decision, which can be a probability value or categorical label. Based on this output, a predefined threshold or rule-based system determines whether to trigger the memory calibration.

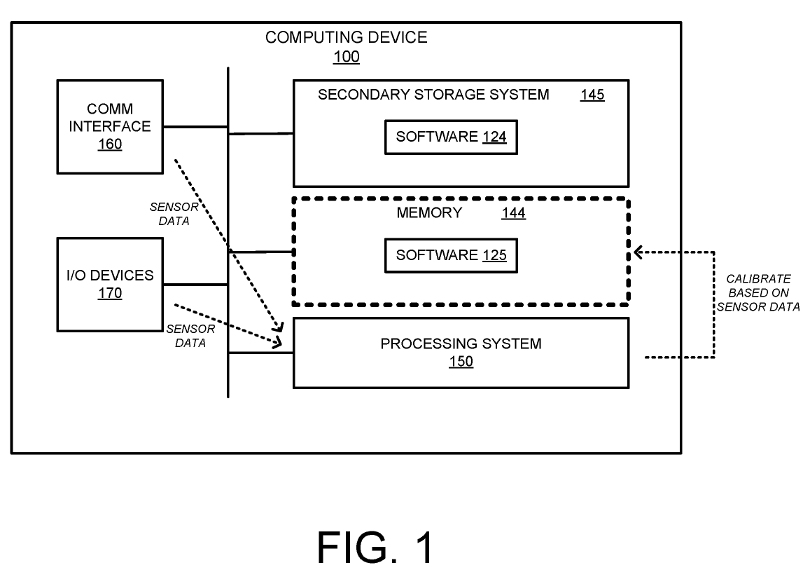

FIG. 1 illustrates a computing device 100 that provides memory calibration according to an implementation. Computing device 100 includes processing system 150, memory 144, secondary storage system 145, communication interface 160, and input/output (I/O) devices 170. Memory 144 and secondary storage system 145 store software 124 and software 125. Computing device 100 represents any computing device with which the various operational architectures, processes, scenarios, and sequences disclosed herein for initiating memory calibration can be implemented. Processing system 150 is operatively linked to communication interface 160, I/O devices 170, memory 144, and secondary storage system 145. In some implementations, communication interface 160 and/or I/O devices 170 can be communicatively linked to secondary storage system 145 and/or memory 144. Computing device 100 may further include other components, such as a battery and enclosure, that are not shown for clarity. Software 124-125 can be used to identify sensor data from I/O devices 170, determine that the sensor data satisfies at least one criterion, and initiate a calibration of memory 144 based on the sensor data satisfying the at least one criterion. Computing device 100 can be an example of a laptop computer, tablet, smartphone, or another computing device.

Communication interface 160 comprises components that communicate over communication links, such as network cards, ports, radio frequency, processing circuitry with software, or some other communication devices. Communication interface 160 may be configured to communicate over metallic, wireless, or optical links. Communication interface 160 may be configured to use Time Division Multiplex (TDM), Internet Protocol (IP), Ethernet, optical networking, wireless protocols, communication signaling, or some other communication format – including combinations thereof. Communication interface 160 may be configured to communicate with external devices, such as servers, user devices, or some other computing device.

I/O devices 170 may include peripherals of a computer that ease the interaction between the user and computing device 100. Examples of I/O devices 170 may include keyboards, mice, trackpads, monitors, displays, printers, cameras, microphones, external storage devices, sensors, and the like. The sensors can provide GPS information, temperature information, humidity information, or some other information associated with computing device 100.

Processing system 150, which includes at least one processor, is designed to execute instructions and perform calculations necessary to operate computing device 100. Processing system 150 represents a control unit, executing program instructions by interpreting and processing data from software 124-125 and the operating system. The at least one processor may include multiple cores, enabling parallel processing to improve computational efficiency and performance. The processing system interfaces with memory components (i./e. memory 144), storage systems (i.e., secondary storage system 145), and input/output peripherals (i.e., I/O devices 170) to facilitate coordinated functionality across the device. Additionally, the processing system may incorporate specialized processors, such as graphics processing units (GPUs), to handle specific computational tasks, including graphical rendering and advanced data processing. Other specialized components can include arithmetic logic unit (ALU) for mathematical and logical operations, the control unit (CU) for instruction execution, registers for temporary data storage, cache for high-speed memory access, and floating-point units (FPU) for advanced numerical calculations.

Processing system 150 is operatively coupled to memory 144 and secondary storage system 145 to execute software 124-125 that performs at least the operations described herein for memory calibration. Memory 144 can refer to the hardware components within computing device 100 that temporarily store data and instructions for processing. It provides a fast and accessible space for processing system 150 to read from and write to while executing tasks. Memory 144 can be volatile memory, such as Random Access Memory (RAM) or Dynamic Random Access Memory (DRAM), and non-volatile memory, such as Read-Only Memory (ROM). RAM is a high-speed, temporary storage medium that holds data that is actively used by processing system 150. ROM is permanent and typically used to store firmware or system-level instructions required during the startup process. Memory 144 is an example of a computer-readable storage medium. DRAM refers to a type of RAM that stores data temporarily using capacitors and transistors, where each bit of data is held as a charge on a capacitor or transistor, requiring periodic "refreshing" to maintain data integrity as the charge can leak over time.

Secondary storage system 145 represents non-volatile storage used to store data and programs permanently. It provides long-term data retention and can have a much larger capacity than memory 144. Examples of secondary storage include hard disk drives (HDDs), solid-state drives (SSDs), optical discs (e.g., CDs and DVDs), and external storage devices such as USB drives. Secondary storage system 145 is an example of a computer-readable storage medium. Unlike memory 144, secondary storage system 145 can retain data when the computing device is powered off. While secondary storage system 145 can be slower than memory 144 in terms of access speed, secondary storage system 145 can be used for the storage of data, including operating systems, applications, and user files. In some examples, the storage media can be non-transitory. In some examples, at least a portion of the storage media may be transitory. In no case is the storage media a propagated signal.

In at least one implementation, software 124-125, when executed by processing system 150, directs processing system 150 and computing device 100 to identify at least one sensor datum from at least one sensor on a computing device. The sensor datum can include a temperature, a value for humidity associated with the device, or a geographic location. Software 124-125 further directs processing system 150 to determine that the at least one sensor datum satisfies at least one criterion. Software 124-125 also directs processing system 150 to start a calibration of memory on the computing device in response to the at least one sensor datum satisfying the at least one criterion.

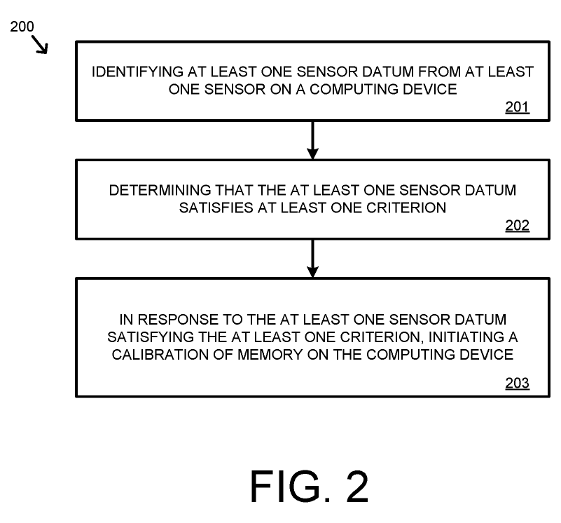

FIG. 2 illustrates a method 200 of operating a computing device to provide memory calibration according to an implementation. The steps of method 200 can be performed by a computing device, such as computing device 100 of FIG. 1. The steps of method 200 are referenced parenthetically in the following paragraphs.

Method 200 includes identifying (201) at least one sensor datum from at least one sensor on a computing device. In some implementations, the computing device can collect data from one or more sensors. The sensors can collect GPS or location data, humidity data for the environment associated with the device, temperature associated with the environment for the device, or other information related to the device. In some examples, the device can be configured to collect the data periodically. In some examples, the device can be configured to collect the data based on a user request. In some examples, the data can be collected based on environmental changes associated with the device. For example, the device can use GPS to determine that the environment has changed for the environment. The device can then collect additional information from one or more additional sensors to identify supplemental information about the current environment.

Method 200 further includes determining (202) that at least one sensor datum satisfies at least one criterion. In some implementations, when the datum comprises a first location for the computing device, the device can be configured to identify a second location for the computing device at a time prior. The criterion is satisfied if the first location differs from the second location by a threshold amount or distance. For example, a user can move from a first location (e.g., first city) to a second location (e.g., second city). Based on the distance exceeding a threshold, the criterion is satisfied.

In some implementations, when the datum comprises a first temperature for the computing device environment, the device can be configured to identify a second temperature for the computing device at a time before detecting the first temperature. The device can consider the criterion satisfied when the temperatures differ by a threshold amount. In some implementations, when the datum comprises a first humidity value for the environment of the computing device, the device can identify a second humidity value for the computing device at a time before detecting the first value. The device can consider the criterion satisfied when the first value differs from the second value by a threshold amount. Although demonstrated as processing the sensor data individually, the device can process sensor data from any number of sensors to determine whether the criterion or criteria are satisfied. In some implementations, the device can also use criteria that are threshold values, where the threshold values do not correspond to a previous measurement. For example, the device can determine that a criterion is satisfied when the temperature satisfies a threshold value.

In some implementations, determining whether the at least one sensor datum satisfies the at least one criterion includes applying a model to the at least one sensor datum to generate an output and determining whether the output satisfies the at least one criterion. In some implementations, the value comprises an output or other numerical value. In some implementations, the model represents a machine learning model. A machine learning model is a program or system trained or configured on data to identify patterns and make predictions or decisions. It learns from past data and uses that knowledge to process new, unseen inputs. In some examples, the machine learning model is configured using sensor data from sensors on the device and memory status information from the device. The memory state can include error information, such as page faults (when a process accesses memory not currently in RAM), out-of-memory errors (when the system runs out of available RAM and swap space), and memory leaks (when applications fail to release unused memory). It can also cover hardware-related errors like Error-Correcting Code (ECC) memory corrections, bad RAM sectors, and segmentation faults caused by invalid memory access. The model can learn to predict the memory state (e.g., determine whether the memory is functional, creating errors, etc.) from the sensor data on the device. In some examples, the model can be configured exclusively on the local device. In some examples, the model can be configured across multiple devices using memory status information and sensor data. The sensor data can be used to predict when a memory calibration is required.

In response to the at least one sensor datum satisfying the at least one criterion, method 200 further includes initiating (203) a calibration of memory on the computing device. Memory calibration on a device can involve optimizing its performance and ensuring reliable operation under various conditions. This process can include configuring parameters like timing, voltage, and frequency to align with the device’s hardware specifications. It may involve running diagnostic tests or benchmarking tools to identify and resolve potential issues such as instability, latency, or errors. In some implementations, the device can determine that the environmental conditions identified from the sensor data will correspond to a recalibration requirement for the device’s memory. The determination can be based at least in part on trends associated with the memory state of the device in association with sensor data identified on the device.

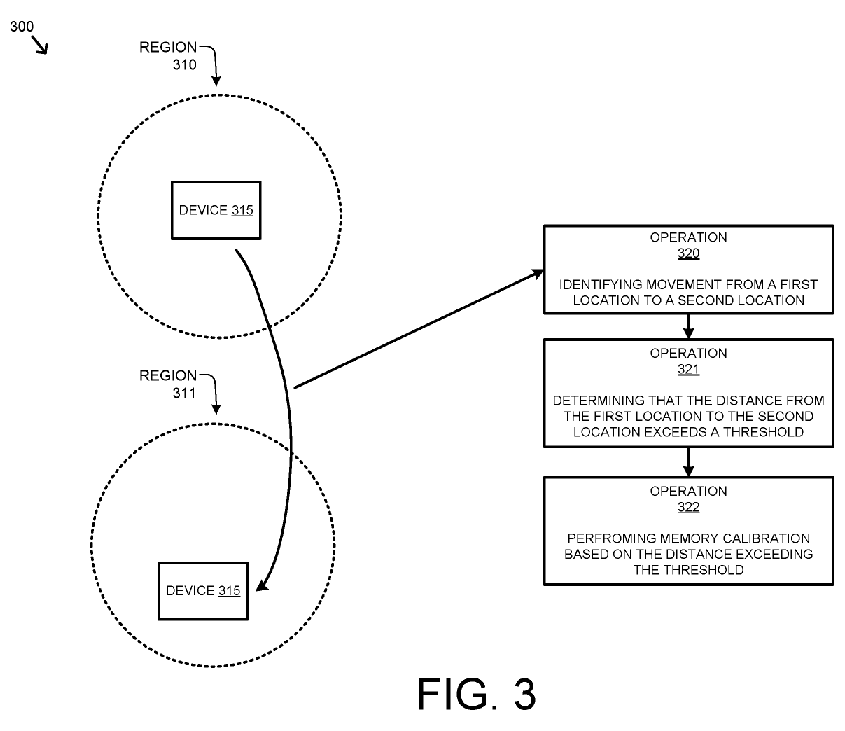

FIG. 3 illustrates an operational scenario 300 of providing memory calibration according to an implementation. Operational scenario 300 includes regions 310-311, device 315, and operations 320-322. Device 315 can represent a mobile device, a laptop computer, a tablet, or another computing device capable of performing operations 320-322.

Device 315 performs operation 320, which includes identifying movement from a first location (region 310) to a second location (region 311). In some implementations, device 315 can determine its geographic location using technologies like the Global Positioning System (GPS), which provides precise latitude and longitude coordinates via satellite signals. Other methods include triangulating signals from nearby cell towers and Wi-Fi networks or using IP address-based geolocation, which estimates location by matching the IP address to a database of known geographic regions.

Device 315 further provides operation 321, which includes determining that the distance from the first location to the second location exceeds a threshold. For example, a user of device 315 may take a flight that moves the device from region 310 to region 311, where region 310 can include a different altitude, temperature, humidity, or other feature from region 311. In response to determining that the distance from the first location to the second location exceeds a threshold, device 315 performs operation 322, which include performing the memory calibration for device 315. Memory calibration can include configuring and fine-tuning system memory (e.g., RAM) settings to optimize performance and ensure stability. This process may include adjusting parameters like memory frequency, voltage, and latency timings in the system's BIOS or firmware. The calibration can be started automatically or upon approval from a user of the device.

Although demonstrated as determining a difference between locations, the device can consider other factors, such as whether the device is in a specific region, whether the device left a particular region, or some other factor. In some implementations, the device can be configured with a model that determines when to perform memory calibration based on the temperature and/or other sensor data on the device. The model can represent a mathematical representation of a system designed to make predictions or decisions based on input data. It is built by training on datasets to identify patterns or relationships, enabling it to generalize new, unseen data. Here, the model can be configured or trained based on sensor data provided by the device and memory status information, which can include error information associated with the memory. Memory errors include soft, hard, parity, error correcting code (ECC), addressing, leakage, access violations, stack overflows, heap corruption, and page faults, while measurements like error rate, Mean Time Between Failures (MTBF), Bit Error Rate (BER), and utilization help assess reliability and performance. The sensor data can be used to determine environmental characteristics or changes that can lead to increased errors in the memory system. As at least one technical effect, the device can predict when potential errors may occur and calibrate the memory before the error occurs.

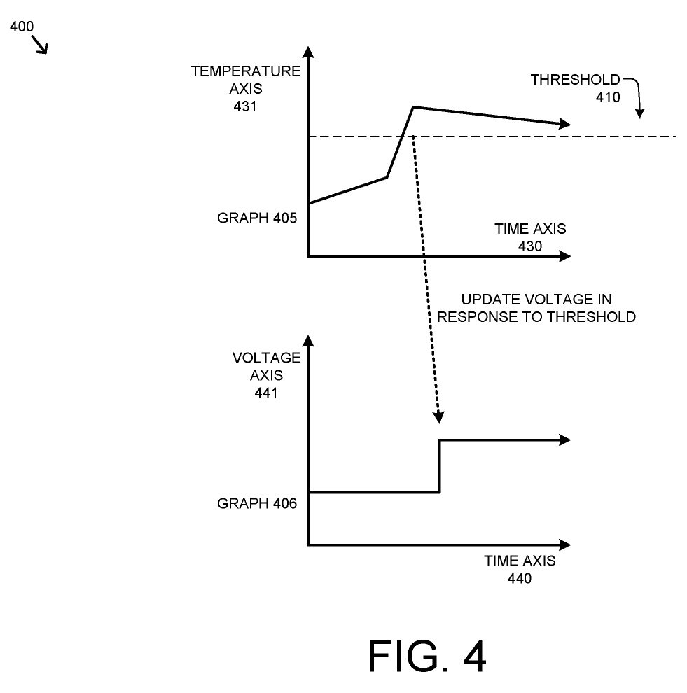

FIG. 4 illustrates an operational scenario 400 of providing memory calibration according to an implementation. Operational scenario 400 includes graph 405 and graph 406. Graph 405 represents a graph of temperature as a temperature axis 431 as a function of time and time axis 430. The temperature crosses a threshold 410 to trigger an update associated with graph 406. Graph 406 represents memory voltage in voltage axis 441 as a function of time and the time axis 440.

As depicted in operational scenario 400, a computing device can monitor the environmental temperature associated with the device. When the temperature satisfies threshold 410, the device can trigger a memory configuration that transitions the memory voltage from a first to a second voltage. In some implementations, the voltage is modified and then tested to determine whether the updated voltage is stable. The voltage can be increased based on the temperature change. In some examples, the memory confirmation may occur for DRAM used in the computing device.

In some examples, rather than exceeding a threshold to initiate the memory calibration, the memory calibration can be initiated when a temperature at a first time differs from a temperature at a second time by a threshold amount. In some implementations, the device can consider additional factors and sensor data to trigger the memory calibration. The various sensors can provide solar radiation information, humidity information, magnetic field information, location information, or other information associated with the device. The information can be used to identify or predict when a memory calibration is required.

In some implementations, the device can be configured with a model that identifies or predicts when to initiate memory calibration based on various sensor data. The model can be configured from sensor data and memory status information to predict or anticipate a requirement for memory calibration. The sensor data can include humidity, temperature, location, or other data associated with the device. The memory status information can include error information associated with the memory. Memory errors include soft, hard, parity, ECC, addressing, leakage, access violations, stack overflows, heap corruption, and page faults, while measurements like error rate, Mean Time Between Failures (MTBF), Bit Error Rate (BER), and utilization help assess reliability and performance of the memory. When errors are identified, the model can associate the errors with sensor data or sensor data trends that correspond to the errors. Future sensor data can initiate memory calibration to prevent future errors. In some implementations, the model is generated on the local device. In other implementations, the model is generated using a set of devices. The set of devices can be from the same manufacturer, can be of the same model, or can be of some other relationship. In some examples, the set of devices can be selected at random. In some implementations, a server computing system or cloud computing system can obtain sensor data from various devices and memory state information or data from various devices (the devices may be the same type or manufacturer in some examples). The system can generate a model from the obtained data and distribute the model to the devices to improve the timing of memory calibration.

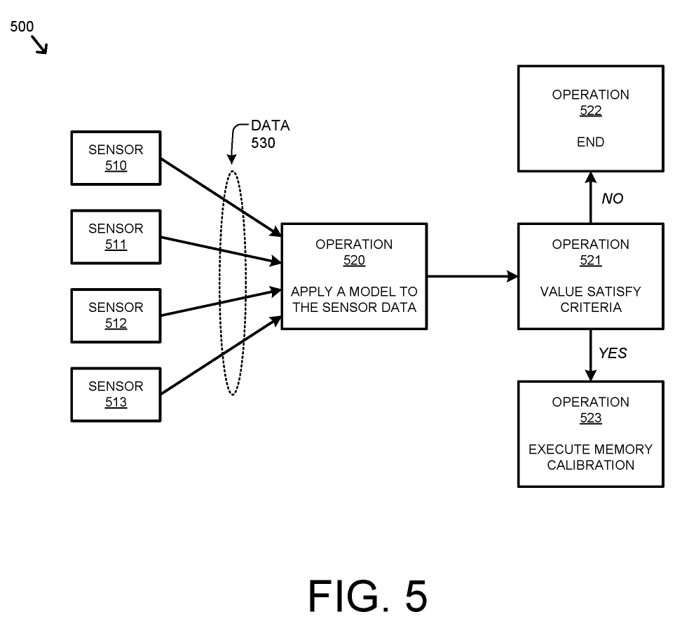

FIG. 5 illustrates an operational scenario 500 of using sensor data to provide memory calibration according to an implementation. Operational scenario 500 includes sensors 510-513, data 530, and operations 520-523 that can be provided by a computing device, such as computing device 100 of FIG. 1.

In operational scenario 500, a computing device performs operation 520 that applies a model to sensor data 530 from sensors, e.g., sensors 510, 511, 512, 513, etc. Sensors 510-513 can be referred to as a set of sensors and can provide solar radiation information, humidity information, magnetic field information, location information, or other information associated with the device. For example, a Wi-Fi module can be used to provide location information associated with the device. In some implementations, operation 520 applies a model to generate a value. The model can generate values by processing input data through a series of mathematical operations based on patterns learned during the configuration or training of the model. The model applies weights and biases to the input features, transforming them layer by layer (in the case of neural networks) or using rules (in simpler models). Depending on the model’s purpose, these transformations produce an output value, such as a prediction, classification, or score. In some implementations, the score or output value is compared to a threshold to determine whether criteria are satisfied for memory calibration at operation 521. The output reflects the model’s learned relationship between inputs and the target during the model’s configuration. In some implementations, the model is configured to predict or associate the requirement of a memory calibration based on memory status information and the collected sensor data.

In operational scenario 500, when the value or output from the model does not satisfy the criteria (e.g., is below a threshold value), operation 522 is performed that prevents or ends any further calibration action associated with the memory. The device can continue to identify sensor data and determine whether the device satisfies the criteria for implementing memory calibration. In some examples, the sensors are polled periodically. In some examples, the sensors are polled when joining a new network. In some examples, the sensors are polled pseudo-randomly or at other intervals. In some implementations, the system executes memory calibration (operation 523) for the device when the value satisfies criteria (e.g., a threshold value). Memory calibration can be performed automatically during downtime for the device (e.g., during off hours or at night), after approval from the user, or at some other time. During memory calibration, adjustments are made to parameters like memory timing (e.g., CAS latency) and clock speed to ensure optimal performance and stability. Voltage levels may also be fine-tuned to prevent errors and ensure compatibility with the hardware.

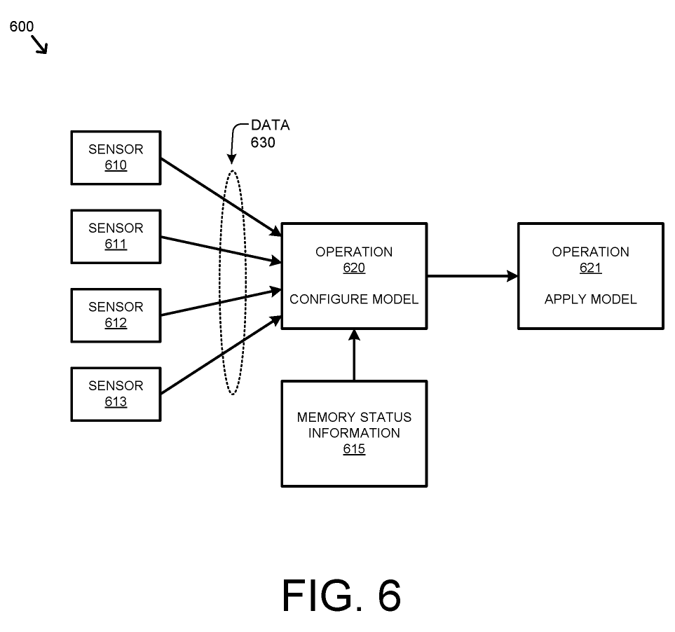

FIG. 6 illustrates an operational scenario 600 of configuring a model to identify memory calibration timing according to an implementation. Operational scenario 600 includes sensors, such as sensors 610, 611, 612, 613, etc., memory status information 615, sensor data 630, and operations 620-621. Operations 620-621 can be performed by a computing device, such as computing device 100 of FIG. 1. Sensors 610-613 can be referred to as a set of sensors and can include any number of (quantity of) sensors.

In operational scenario 600, operation 620 receives sensor data 630 and memory status information 615. Sensor data 630 can include solar radiation information, humidity information, magnetic field information, location information, or other information associated with the device. Sensors 610-613 can consist of a pyranometer, a hygrometer, a magnetometer, a Wi-Fi sensor, a GPS sensor, or other sensors. Memory status information 615 can include error information associated with the memory. Memory errors include soft, hard, parity, ECC, addressing, leakage, access violations, stack overflows, heap corruption, and page faults. In some implementations, memory status information 615 can include error rate, MTBF, BER, and memory utilization. Operation 620 processes sensor data 630 and memory status information 615 to generate or configure a model. In some implementations, the model represents a machine learning model, which is a program or mathematical algorithm trained to recognize patterns in data and make predictions or decisions based on it. It learns from input data through training, identifying relationships and trends that can be generalized to new, unseen data. Here, the model is configured to obtain the data from sensors 610-613 and use the data to predict when a memory calibration is required based on the associated memory status information 615. The model can be configured to identify when potential memory errors occur associated with sensor data from sensors 610-613. The model can include decision trees for structured decision-making, neural networks, or other machine learning models that can determine when a calibration is required based on sensor data.

Once the model is configured, the device performs operation 621 to apply the model to the sensor data and initiate memory calibration. The model is updated in some implementations using additional sensor data and memory status information. In some implementations, sensor and memory status information from multiple devices can be used to configure the model rather than using the data from a single device. The information from multiple devices can provide at least one technical effect of providing additional data points for the model’s accuracy.

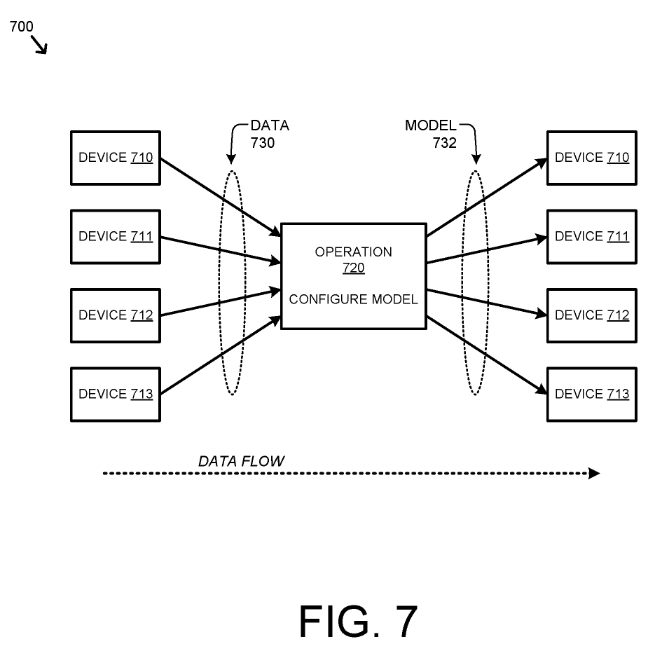

FIG. 7 illustrates an operational scenario 700 of using sensor data across multiple devices to configure a model associated with memory calibration timing according to an implementation. Operational scenario 700 includes devices 710, 711, 712, and 713, operation 720, data 730, and model 732. Devices 710-713 represent computing devices, such as smartphones, tablets, laptop computers, or other computing devices, including combinations thereof. Devices 710-713 can also be referred to as a set of devices. Operation 720 can be provided by one or more computing devices, including server computers, desktop computers, or other computing devices. In some implementations, at least a portion of operation 720 is implemented on a local device, such as any device from devices 710-713. In some implementations, operation 720 can be performed on a computing device, such as a computing device 100 of FIG. 1, or a set of computing devices, such as examples of computing device 100 of FIG. 1.

In operational scenario 700, devices 710-713 provide data 730 to operation 720 provided by one or more computing devices. Data 730 can include sensor data and memory status information. The sensor data can include humidity, temperature, location, altitude, or other data associated with each of devices 710-713. Memory status information can include information regarding potential errors or status associated with the memory on each of devices 710-713. Memory status information can consist of error details such as memory faults, hardware errors, or issues like memory leaks. It can further include information about memory usage, paging errors, or other information about the memory status of the individual devices. In some examples, data 730 is provided via a network connection or the internet. In some examples, data 730 is provided periodically, during downtime of the device, or at another interval to the one or more computing devices generating the model.

When data 730 is received, operation 720 configures a model 732 that can be distributed to devices 710-713. In some implementations, model 732 represents a machine learning model. The machine learning model can include a computational algorithm designed to recognize patterns, make predictions, or generate insights based on data. It is built by training on a dataset, where it learns to identify relationships between input features (i.e., the sensor data from the various data devices) and target outputs (i.e., memory conditions requiring a memory calibration). The training or configuration process can involve optimizing parameters using mathematical techniques such as gradient descent to minimize error and improve performance over time. Machine learning models can be classified into different types, including supervised learning (where labeled data is used to guide learning), unsupervised learning (where the model finds structure in unlabeled data), and reinforcement learning (where an agent learns by interacting with an environment and receiving rewards or penalties). Once trained, model 732 can be distributed to the various devices 710-713 and applied by each of the devices.

In at least one implementation, when implemented on a device, such as device 710, the model can receive inputs of sensor data from the device. In some examples, the retrieval of the sensor data is periodic, based on a change of location (identified via GPS or Wi-Fi network change), or at some other interval. Model 732 is applied to the sensor data to generate an output, wherein the output indicates whether a memory calibration is required. In some implementations, the device preprocesses the sensor data through normalization, filtering, or feature extraction. Normalization is scaling sensor data to a standard range (e.g., 0 to 1 or -1 to 1) to ensure that different input values do not disproportionately affect a machine learning model. Filtering involves removing noise or irrelevant variations from sensor input using techniques like moving averages, low-pass filters, or median filters. Feature extraction can transform raw sensor data into meaningful attributes that improve a model’s ability to recognize patterns. This may include computing statistical measures (e.g., mean, variance), identifying frequency components (e.g., via Fourier transform), or detecting key signal patterns relevant to the decision-making process.

The preprocessed data is then fed into the configured model, which has learned patterns from historically labeled examples from devices 710-713. Using techniques like classification, regression, or anomaly detection, the model evaluates the input against its learned parameters and generates an output decision, which can be a probability value or categorical label. Based on this output, a predefined threshold or rule-based system determines whether to trigger the memory calibration. In some implementations, the memory calibration occurs automatically. In some implementations, the user approves the memory calibration. In some implementations, the system waits for a restart or downtime (e.g., sleep for a computer or device) to provide the memory calibration. The memory calibration can include Memory calibration typically involves adjusting a computer’s memory (RAM) settings to ensure optimal performance, stability, and compatibility. This process can include setting the correct voltage, frequency, and timing values in the BIOS/UEFI, running stress tests to detect errors, and fine-tuning configurations based on the device requirements.

Examples of potential claim clauses are provided below. However, the list of clauses should not be considered exhaustive.

Clause 1. A method comprising: identifying at least one sensor datum from at least one sensor on a computing device; determining that the at least one sensor datum satisfies at least one criterion; and in response to the at least one sensor datum satisfying the at least one criterion, initiating a calibration of memory on the computing device.

Clause 2. The method of clause 1, further comprising: identifying sensor data from a set of sensors; determining a memory state associated with the sensor data; and generating a model based on the sensor data and the memory state, wherein determining that the at least one sensor datum satisfies the at least one criterion comprises: applying the model to the at least one sensor datum to generate an output; and determining that the output satisfies the at least one criterion.

Clause 3. The method of any of the preceding clauses, wherein the at least one sensor datum comprises a first geographic location for the computing device at a first time, and wherein determining that the at least one sensor datum satisfies the at least one criterion comprises: identifying a second geographic location for the computing device at a second time occurring before the first time; and determining that the first geographic location differs from the second geographic location by a threshold distance.

Clause 4. The method of any of the preceding clauses, wherein the at least one sensor datum comprises a first temperature for the computing device at a first time and wherein determining that the at least one sensor datum satisfies the at least one criterion comprises: identifying a second temperature for the computing device measured at a second time before the first time; and determining that the first temperature differs from the second temperature by a threshold amount.

Clause 5. The method of any of the preceding clauses, wherein the at least one sensor datum comprises a first humidity value measured at a first time and wherein determining that the at least one sensor datum satisfies the at least one criterion comprises: identifying a second humidity value measured at a second time before the first time; and determining that the first humidity value differs from the second humidity value by a threshold amount.

Clause 6. The method of any of the preceding clauses, wherein the at least one sensor datum comprises a temperature, a humidity value, and a geographic location.

Clause 7. The method of any of the preceding clauses, further comprising: identifying sensor data from the computing device and at least one additional computing device; obtaining memory state information for the computing device and the at least one additional computing device, the memory state information associated with the sensor data; and generating a model based on the sensor data and the memory state information.

Clause 8. A computer-readable storage medium having program instructions stored thereon that, when executed by at least one processor, direct the at least one processor to perform a method, the method comprising: identifying at least one sensor datum from at least one sensor on a computing device; determining that the at least one sensor datum satisfies at least one criterion; and in response to the at least one sensor datum satisfying the at least one criterion, initiating a calibration of memory on the computing device.

Clause 9. The computer-readable storage medium of clause 8, wherein the method further comprises: identifying sensor data from a set of sensors; determining a memory state associated with the sensor data; and generating a model based on the sensor data and the memory state, wherein determining that the at least one sensor datum satisfies the at least one criterion comprises: applying the model to the at least one sensor datum to generate an output; and determining that the output satisfies the at least one criterion.

Clause 10. The computer-readable storage medium of clauses 8 or 9, wherein the at least one sensor datum comprises a first geographic location for the computing device at a first time, and wherein determining that the at least one sensor datum satisfies the at least one criterion comprises: identifying a second geographic location for the computing device at a second time occurring before the first time; and determining that the first geographic location differs from the second geographic location by a threshold distance.

Clause 11. The computer-readable storage medium of clauses 8-10, wherein the at least one sensor datum comprises a first geographic location for the computing device at a first time, and wherein determining that the at least one sensor datum satisfies the at least one criterion comprises: identifying a second geographic location for the computing device measured at a second time before the first time; and determining that the first geographic location differs from the second geographic location by a threshold amount.

Clause 12. The computer-readable storage medium of clauses 8-11, wherein the at least one sensor datum comprises a first temperature for the computing device at a first time and wherein determining that the at least one sensor datum satisfies the at least one criterion comprises: identifying a second temperature for the computing device at a second time before the first time; and determining that the first temperature differs from the second temperature by a threshold amount.

Clause 13. The computer-readable storage medium of clauses 8-12, wherein the at least one sensor datum comprises a first humidity value measured at a first time and wherein determining that the at least one sensor datum satisfies the at least one criterion comprises: identifying a second humidity value measured at a second time before the first time; and determining that the first humidity value differs from the second humidity value by a threshold amount.

Clause 14. The computer-readable storage medium of clauses 8-13, wherein the at least one sensor datum comprises a temperature, a humidity value, or a geographic location.

Clause 15. A computing apparatus comprising: a computer-readable storage media; at least one processor operatively coupled to the computer-readable storage media; and program instructions stored on the computer-readable storage media that, when executed by the at least one processor, direct the computing apparatus to perform a method, the method comprising: identifying at least one sensor datum from at least one sensor on a computing device; determining that the at least one sensor datum satisfies at least one criterion; and in response to the at least one sensor datum satisfying the at least one criterion, initiating a calibration of memory on the computing device.

Clause 16. The computing apparatus of clause 15, wherein the method further comprises: identifying sensor data from a set of sensors; determining a memory state associated with the sensor data; and generating a model based on the sensor data and the memory state, wherein determining that the at least one sensor datum satisfies the at least one criterion comprises: applying the model to the at least one sensor datum to generate an output; and determining that the output satisfies the at least one criterion.

Clause 17. The computing apparatus of clauses 15 or 16, wherein the at least one sensor datum comprises a first geographic location for the computing device at a first time, and wherein determining that the at least one sensor datum satisfies the at least one criterion comprises: identifying a second geographic location for the computing device at a second time occurring before the first time; and determining that the first geographic location differs from the second geographic location by a threshold distance.

Clause 18. The computing apparatus of clauses 15 to 17, wherein the at least one sensor datum comprises a first temperature for the computing device at a first time and wherein determining that the at least one sensor datum satisfies the at least one criterion comprises: identifying a second temperature for the computing device measured at a second time before the first time; and determining that the first temperature differs from the second temperature by a threshold amount.

Clause 19. The computing apparatus of clauses 15 to 18, wherein the at least one sensor datum comprises a first humidity value measured at a first time and wherein determining that the at least one sensor datum satisfies the at least one criterion comprises: identifying a second humidity value measured at a second time before the first time; and determining that the first humidity value differs from the second humidity value by a threshold amount.

Clause 20. The computing apparatus of clauses 15-19 further comprising: identifying sensor data from a set of sensors; identifying a memory state associated with the sensor data; communicating the sensor data and the memory state to at least one second computing device; and receiving a model from the at least one second computing device; wherein determining that the at least one sensor datum satisfies the at least one criterion comprises: applying the model to the at least one sensor datum to generate an output; and determining that the output satisfies the at least one criterion.

In this specification and the appended claims, the singular forms “a,” “an” and “the” do not exclude the plural reference unless the context dictates otherwise. Further, conjunctions such as “and,” “or,” and “and/or” are inclusive unless the context dictates otherwise. For example, “A and/or B” includes A alone, B alone, and A with B. Further, connecting lines or connectors shown in the various figures presented are intended to represent example functional relationships and/or physical or logical couplings between the various elements. Many alternative or additional functional relationships, physical connections, or logical connections may be present in a practical device. Moreover, no item or component is essential to the practice of the implementations disclosed herein unless the element is specifically described as “essential” or “critical.”

Terms such as, but not limited to, approximately, substantially, generally, etc. are used herein to indicate that a precise value or range thereof is not required and need not be specified. As used herein, the terms discussed above will have ready and instant meaning to one of ordinary skill in the art.

Moreover, the use of terms such as up, down, top, bottom, side, end, front, back, etc. herein are used concerning a currently considered or illustrated orientation. If they are considered concerning another orientation, such terms must be correspondingly modified.

Further, in this specification and the appended claims, the singular forms “a,” “an” and “the” do not exclude the plural reference unless the context dictates otherwise. Moreover, conjunctions such as “and,” “or,” and “and/or” are inclusive unless the context dictates otherwise. For example, “A and/or B” includes A alone, B alone, and A with B.

Although certain example methods, apparatuses, and articles of manufacture have been described herein, the scope of coverage of this patent is not limited thereto. It is to be understood that the terminology employed herein is to describe aspects and is not intended to be limiting. On the contrary, this patent covers all methods, apparatus, and articles of manufacture fairly falling within the scope of the claims of this patent.

What is claimed is:

1. A method comprising:
identifying at least one sensor datum from at least one sensor on a computing device;
determining that the at least one sensor datum satisfies at least one criterion; and
in response to the at least one sensor datum satisfying the at least one criterion, initiating a calibration of memory on the computing device.

2. The method of claim 1, further comprising:
identifying sensor data from a set of sensors;
determining a memory state associated with the sensor data; and
generating a model based on the sensor data and the memory state,
wherein determining that the at least one sensor datum satisfies the at least one criterion comprises:
applying the model to the at least one sensor datum to generate an output; and
determining that the output satisfies the at least one criterion.

3. The method of claim 1, wherein the at least one sensor datum comprises a first geographic location for the computing device at a first time, and wherein determining that the at least one sensor datum satisfies the at least one criterion comprises:
identifying a second geographic location for the computing device at a second time occurring before the first time; and
determining that the first geographic location differs from the second geographic location by a threshold distance.

4. The method of claim 1, wherein the at least one sensor datum comprises a first temperature for the computing device at a first time, and wherein determining that the at least one sensor datum satisfies the at least one criterion comprises:
identifying a second temperature for the computing device measured at a second time before the first time; and
determining that the first temperature differs from the second temperature by a threshold amount.

5. The method of claim 1, wherein the at least one sensor datum comprises a first humidity value measured at a first time, and wherein determining that the at least one sensor datum satisfies the at least one criterion comprises:
identifying a second humidity value measured at a second time before the first time; and
determining that the first humidity value differs from the second humidity value by a threshold amount.

6. The method of claim 1, wherein the at least one sensor datum comprises a temperature, a humidity value, and a geographic location.

7. The method of claim 1, further comprising:
identifying sensor data from the computing device and at least one additional computing device;
obtaining memory state information for the computing device and the at least one additional computing device, the memory state information associated with the sensor data; and
generating a model based on the sensor data and the memory state information.

8. A computer-readable storage medium having program instructions stored thereon that, when executed by at least one processor, direct the at least one processor to perform a method, the method comprising:
identifying at least one sensor datum from at least one sensor on a computing device;
determining that the at least one sensor datum satisfies at least one criterion; and
in response to the at least one sensor datum satisfying the at least one criterion, initiating a calibration of memory on the computing device.

9. The computer-readable storage medium of claim 8, wherein the method further comprises:
identifying sensor data from a set of sensors;
determining a memory state associated with the sensor data; and
generating a model based on the sensor data and the memory state,
wherein determining that the at least one sensor datum satisfies the at least one criterion comprises:
applying the model to the at least one sensor datum to generate an output; and
determining that the output satisfies the at least one criterion.

10. The computer-readable storage medium of claim 8, wherein the at least one sensor datum comprises a first geographic location for the computing device at a first time, and wherein determining that the at least one sensor datum satisfies the at least one criterion comprises:
identifying a second geographic location for the computing device at a second time occurring before the first time; and
determining that the first geographic location differs from the second geographic location by a threshold distance.

11. The computer-readable storage medium of claim 8, wherein the at least one sensor datum comprises a first geographic location for the computing device at a first time, and wherein determining that the at least one sensor datum satisfies the at least one criterion comprises:
identifying a second geographic location for the computing device measured at a second time before the first time; and
determining that the first geographic location differs from the second geographic location by a threshold amount.

12. The computer-readable storage medium of claim 8, wherein the at least one sensor datum comprises a first temperature for the computing device at a first time, and wherein determining that the at least one sensor datum satisfies the at least one criterion comprises:
identifying a second temperature for the computing device at a second time before the first time; and
determining that the first temperature differs from the second temperature by a threshold amount.

13. The computer-readable storage medium of claim 8, wherein the at least one sensor datum comprises a first humidity value measured at a first time, and wherein determining that the at least one sensor datum satisfies the at least one criterion comprises:
identifying a second humidity value measured at a second time before the first time; and
determining that the first humidity value differs from the second humidity value by a threshold amount.

14. The computer-readable storage medium of claim 8, wherein the at least one sensor datum comprises a temperature, a humidity value, or a geographic location.

15. A computing apparatus comprising:
a computer-readable storage media;
at least one processor operatively coupled to the computer-readable storage media; and
program instructions stored on the computer-readable storage media that, when executed by the at least one processor, direct the computing apparatus to perform a method, the method comprising:
identifying at least one sensor datum from at least one sensor on a computing device;
determining that the at least one sensor datum satisfies at least one criterion; and
in response to the at least one sensor datum satisfying the at least one criterion, initiating a calibration of memory on the computing device.

16. The computing apparatus of claim 15, wherein the method further comprises:
identifying sensor data from a set of sensors;
determining a memory state associated with the sensor data; and
generating a model based on the sensor data and the memory state,
wherein determining that the at least one sensor datum satisfies the at least one criterion comprises:
applying the model to the at least one sensor datum to generate an output; and
determining that the output satisfies the at least one criterion.

17. The computing apparatus of claim 15, wherein the at least one sensor datum comprises a first geographic location for the computing device at a first time, and wherein determining that the at least one sensor datum satisfies the at least one criterion comprises:
identifying a second geographic location for the computing device at a second time occurring before the first time; and
determining that the first geographic location differs from the second geographic location by a threshold distance.

18. The computing apparatus of claim 15, wherein the at least one sensor datum comprises a first temperature for the computing device at a first time, and wherein determining that the at least one sensor datum satisfies the at least one criterion comprises:
identifying a second temperature for the computing device measured at a second time before the first time; and
determining that the first temperature differs from the second temperature by a threshold amount.

19. The computing apparatus of claim 15, wherein the at least one sensor datum comprises a first humidity value measured at a first time, and wherein determining that the at least one sensor datum satisfies the at least one criterion comprises:
identifying a second humidity value measured at a second time before the first time; and
determining that the first humidity value differs from the second humidity value by a threshold amount.

20. The computing apparatus of claim 15 further comprising:
identifying sensor data from a set of sensors;
identifying a memory state associated with the sensor data;
communicating the sensor data and the memory state to at least one second computing device; and
receiving a model from the at least one second computing device;
wherein determining that the at least one sensor datum satisfies the at least one criterion comprises:
applying the model to the at least one sensor datum to generate an output; and
determining that the output satisfies the at least one criterion.
